(19) United States
(12) Patent Application Publication
(10) Pub. No.: US 2026/0141132 A1
(43) Pub. Date: May 21, 2026

(54) APPARATUS FOR VISUALIZING ROLLING PROCESS INFORMATION

(71) Applicant: TMEIC Corporation, Tokyo (JP)

(72) Inventor: Hideho GOUDO, Tokyo (JP)

(73) Assignee: TMEIC Corporation, Tokyo (JP)

(21) Appl. No.: 19/119,426

(22) PCT Filed: Sep. 13, 2023
(86) PCT No.: PCT/JP2023/033390

§ 371 Date: Apr. 9, 2025

(51) Int. Cl. G06F 30/17; G06T 13/20

(52) U.S. Cl. CPC G06F 30/17; G06T 13/20; G06T 2200/24

(57) ABSTRACT

The present apparatus is an apparatus for visualizing rolling process information of a rolling line. The present apparatus includes a specification information memory in which specification information of each of rolling equipment installed in the rolling line and a material to be rolled processed in the rolling line is registered, a program memory storing a plurality of executable instructions, and one or more processors communicatively coupled to the specification information memory and the program memory. The plurality of instructions is configured to cause the one or more processors to acquire the rolling process information in real time from a control system that controls the rolling line, generate three-dimensional visualization information for visualizing at least one of the rolling equipment and the material to be rolled in a three-dimensional representation using the rolling process information and the specification information, and display the three-dimensional visualization information on a display device.

### TECHNICAL FIELD

The present disclosure relates to an apparatus for visualizing rolling process information of a rolling line of a steel plant.

### BACKGROUND ART

In a rolling line of a steel plant, it is important to accurately grasp rolling process information including information on rolling equipment and a material to be rolled. Therefore, conventionally, a method of providing various rolling process information in a visually easily understandable manner by using an image device called an industrial television (ITV), animation display on a screen of a human machine interface (HMI), or the like has been used. For example, Patent Document 1 proposes a production result image display system that stores a moving image captured by a camera of the process of a product being produced and an image based on production-related data as one moving image file, thereby quickly providing an image indicating a production result of the product.

On the other hand, there may be a place where no camera is installed in the rolling line. In addition, since the capturing range of a moving image by a camera is limited, there may be a place that becomes a blind spot of the camera. In these places, it is difficult to visually and accurately grasp the rolling process information, and the grasping of the state of the rolling process is restricted. This hinders correct situation determination and causes a wrong countermeasure in improving equipment maintenance and improving yield by improving product quality.

### PRIOR ART DOCUMENT

### Patent Document

Patent Document 1: JP 2015-64665A

### SUMMARY OF THE INVENTION

### Problems to be Solved by the Invention

The present disclosure has been made in view of the above problem. An object of the present disclosure is to enable detailed and easy grasp of the state of a rolling process in a rolling line of a steel plant.

### Solution to Problem

The present disclosure provides an apparatus for achieving the above object.

An apparatus according to a first aspect of the present disclosure is an apparatus for visualizing rolling process information of a rolling line, and includes a specification information memory, a program memory, and one or more processors. In the specification information memory, specification information of each of rolling equipment installed in the rolling line and a material to be rolled processed in the rolling line is registered. The program memory stores a plurality of executable instructions. The one or more processors are communicatively coupled to the specification information memory and the program memory. The plurality of instructions stored in the program memory are configured to cause the one or more processors to: acquire the rolling process information in real time from a control system that controls the rolling line; generate three-dimensional visualization information for visualizing at least one of the rolling equipment and the material to be rolled in a three-dimensional representation using the rolling process information and the specification information; and display the three-dimensional visualization information on a display device. The three-dimensional visualization information may include three-dimensional operation information of at least one of the rolling equipment and the material to be rolled. The three-dimensional visualization information may further include imaging information representing one-dimensional information of at least one of the rolling equipment and the material to be rolled as an image.

An apparatus of a second aspect of the present disclosure is the apparatus of the first aspect, further including an information storage in which the three-dimensional visualization information is stored. According to the apparatus of the second aspect, the plurality of instructions are configured to further cause the one or more processors to: receive a designated period input to a user interface; acquire the three-dimensional visualization information for the designated period from the information storage; and display the three-dimensional visualization information for the designated period on the display device. The instructions may further cause the one or more processors to receive a designated speed input to the user interface, and display the three-dimensional visualization information for the designated period on the display device at the designated speed. Furthermore, the plurality of instructions may further cause the one or more processors to display the three-dimensional visualization information and the three-dimensional visualization information for the designated period in parallel on the display device, or to display the three-dimensional visualization information and the three-dimensional visualization information for the designated period in a superimposed manner on the display device.

An apparatus of a third aspect of the present disclosure is the apparatus of the first aspect, further including an information storage in which the rolling process information is stored. According to the apparatus of the third aspect, the plurality of instructions are configured to further cause the one or more processors to: receive a designated period input to a user interface; acquire the rolling process information for the designated period from the information storage; generate three-dimensional visualization information of at least one of the rolling equipment and the material to be rolled for the designated period using the rolling process information and the specification information for the designated period; and display the three-dimensional visualization information for the designated period on the display device.

An apparatus of a fourth aspect of the present disclosure is the apparatus of the first aspect, further including a simulation information generator configured to generate simulation information simulating the rolling process information. According to the apparatus of the fourth aspect, the plurality of instructions are configured to: generate simulated three-dimensional visualization information of at least one of the rolling equipment and the material to be rolled using the simulation information and the specification information; and display the simulated three-dimensional visualization information on the display device. The simulation information may be information simulating normal rolling process information or information simulating abnormal rolling process information.

### Effects of the Invention

According to the present disclosure, at least one of the rolling equipment and the material to be rolled is visualized by the three-dimensional representation, and thus a manager who manages the rolling line of the steel plant can grasp the state of the rolling process in detail and easily.

This improves equipment maintenance, improves product quality, and improves yield.

### BRIEF DESCRIPTION OF DRAWINGS

FIG. 1 is a block diagram illustrating a configuration of a system according to a first embodiment of the present disclosure.

FIG. 2 is a block diagram illustrating functions of the system according to the first embodiment of the present disclosure.

FIG. 3 is a view illustrating an example of a three-dimensional display of a rolling line.

FIG. 4 is a view illustrating an example of a three-dimensional display of rolling equipment constituting a rolling line.

FIG. 5 is a view illustrating an example of a three-dimensional display of a material to be rolled.

FIG. 6 is a block diagram illustrating a configuration of a system according to a second embodiment of the present disclosure.

FIG. 7 is a block diagram illustrating a first function of the system according to the second embodiment of the present disclosure.

FIG. 8 is a block diagram illustrating a second function of the system according to the second embodiment of the present disclosure.

FIG. 9 is a diagram illustrating an example of a display mode of a three-dimensional animation by the first function and the second function of the system according to the second embodiment of the present disclosure.

FIG. 10 is a block diagram illustrating a third function of the system according to the second embodiment of the present disclosure.

FIG. 11 is a diagram illustrating an example of a first display mode of a three-dimensional animation by the third function of the system according to the second embodiment of the present disclosure.

FIG. 12 is a diagram illustrating an example of a second display mode of a three-dimensional animation by the third function of the system according to the second embodiment of the present disclosure.

FIG. 13 is a block diagram illustrating a configuration of a system according to a third embodiment of the present disclosure.

FIG. 14 is a block diagram illustrating a first function of the system according to the third embodiment of the present disclosure.

FIG. 15 is a block diagram illustrating a second function of the system according to the third embodiment of the present disclosure.

FIG. 16 is a block diagram illustrating a third function of the system according to the third embodiment of the present disclosure.

FIG. 17 is a block diagram illustrating a configuration of a system according to a fourth embodiment of the present disclosure.

FIG. 18 is a block diagram illustrating functions of the system according to the fourth embodiment of the present disclosure.

### DETAILED DESCRIPTION OF THE INVENTION

### 1. First Embodiment

### 1-1. Configuration Of Visualization System Of First Embodiment

A system according to a first embodiment of the present disclosure will be described with reference to the drawings. The system according to the present embodiment is a system for visualizing and displaying rolling process information of a rolling line of a steel plant by a three-dimensional representation. Hereinafter, the system according to the present embodiment is referred to as a visualization system. Note that systems according to second to fourth embodiments described later are also systems for visualizing rolling process information of the rolling line of the steel plant, similarly to the system according to the present embodiment.

These systems are also referred to as visualization systems.

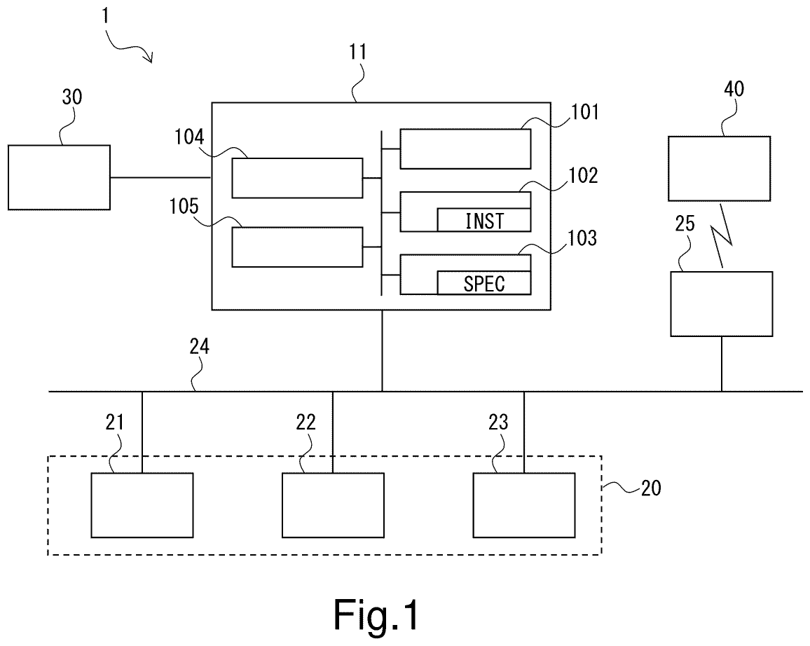

The configuration of the visualization system according to the present embodiment will be described with reference to FIG. 1. The visualization system 1 according to the present embodiment visualizes and displays the rolling process information provided from a control system 20 in a three-dimensional representation. The control system 20 includes a process computer 21 that performs process calculation for controlling the rolling process, a controller 22 that controls actuators of the rolling line in accordance with a calculation result of the process computer 21, and a data collection system 23 that collects rolling process information. The rolling process information is information indicating the current state of the rolling process, and is collected from the process computer 21, the controller 22, and a large number of process sensors (not shown) installed in the rolling line. The process computer 21, the controller 22, the data collection system 23, and the process sensors are connected to each other via a control network 24.

The visualization system 1 includes a visualization apparatus 11 that visualizes rolling process information, and a three-dimensional animation display device 30 and an XR (cross reality) display device 40 as three-dimensional display devices. The visualization apparatus 11 is connected to the control network 24. The rolling process information collected by the data collection system 23 is transmitted in real time from the data collection system 23 to the visualization apparatus 11 via the control network 24.

The visualization apparatus 11 includes a processor 101, a program memory 102, a specification information memory 103, a communication module 104, and a user interface 105. The processor 101 may be a CPU, a GPU, a RISC, a DSP, an FPGA, an ASIC, a PLD, or another processing unit, or a combination of two or more of them, or a dedicated processor for the visualization apparatus 11. In the present embodiment, the number of the processor 101 is one, but the visualization apparatus 11 may include a plurality of processors 101.

The program memory 102 is communicatively coupled to the processor 101. The program memory 102 stores a program including a plurality of instructions INST executable by the processor 101. The program configured by the instructions INST can be acquired by using a computer-readable non-transitory storage medium or can be acquired via a network. The program memory 102 may be built in the processor 101.

The specification information memory 103 is communicatively coupled to the processor 101. The specification information memory 103 stores specification information SPEC of each of the rolling equipment installed in the rolling line and the material to be rolled which is processed in the rolling line. The specification information SPEC includes information not included in the rolling process information but necessary for generating three-dimensional visualization information described later, such as the position, angle, and dimension of the rolling equipment, the position, angle, and dimension of each device constituting the rolling equipment, and the end shape and dimension of the material to be rolled in the middle of processing at each stage. The specification information SPEC can be acquired via a network. The specification information memory 103 may be incorporated in the processor 101.

The communication module 104 is communicatively coupled to the processor 101. The communication module 104 is provided for communication with external devices. The external devices include the data collection system 23, which is an input source of rolling process information, and the three-dimensional animation display device 30 and the XR display device 40, which are output destinations of three-dimensional visualization information described later. The user interface 105 is communicatively coupled to the processor 101. The user interface 105 is provided for entry of information by the rolling line operator. The specification information SPEC can be registered by manual input of the manager via the user interface 105.

The three-dimensional animation display device 30 is a device for displaying three-dimensional visualization information, which will be described later, in the form of a three-dimensional animation. The three-dimensional animation display device 30 is connected to the visualization apparatus 11 by wire. However, the three-dimensional animation display device 30 and the visualization apparatus 11 may be connected wirelessly. The three-dimensional animation display device 30 may be integrated with the visualization apparatus 11.

The XR display device 40 is a device for displaying three-dimensional visualization information, which will be described later, in the form of a three-dimensional hologram. The XR display device 40 is wirelessly connected to the wireless communication device 25 on the control network 24. The XR display device 40 communicates with the visualization apparatus 11 via the wireless communication device 25. However, the XR display device 40 and the visualization apparatus 11 may be connected by wire.

### 1-2. Functions of Visualization System of First Embodiment

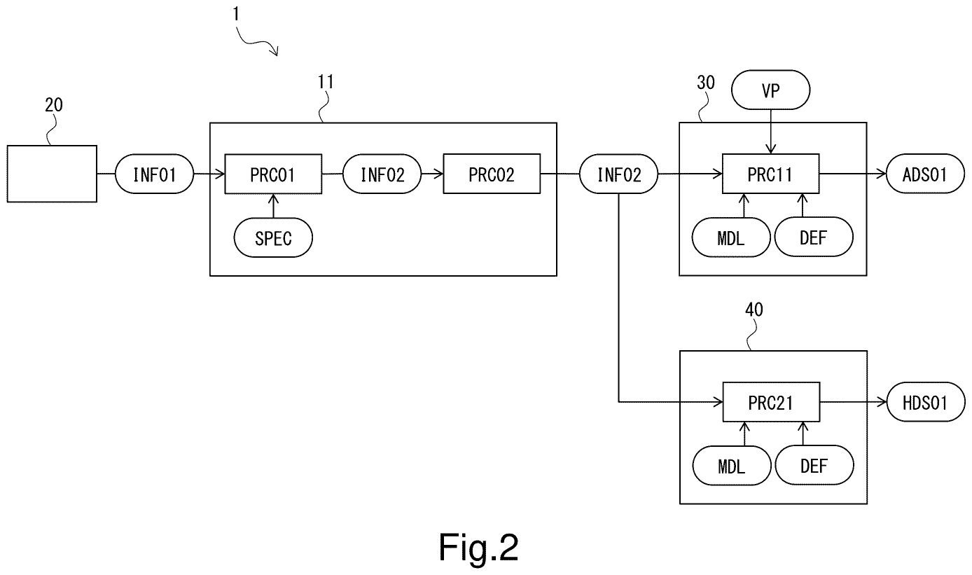

The functions of the visualization system 1 configured as described above will be described with reference to FIG. 2. Note that, among the functions of the visualization system 1 described below, the functions of the visualization apparatus 11 are functions realized by the instructions INST being read from the program memory 102 and executed by the processor 101.

First, the visualization apparatus 11 acquires the rolling process information INF01 from the control system 20 in real time. The visualization apparatus 11 executes processing PRC01 by using the rolling process information INF01 and the specification information SPEC. The processing PRC01 is processing of generating the three-dimensional visualization information INF02. The three-dimensional visualization information INF02 is information for visualizing the rolling equipment and the material to be rolled in a three-dimensional representation. The three-dimensional visualization information INF02 is generated by editing and integrating the rolling process information INF01 based on the specification information SPEC. The three-dimensional visualization information INF02 includes three-dimensional operation information of the rolling equipment and the material to be rolled and imaging information in which one-dimensional information of the rolling equipment and the material to be rolled is represented by an image.

In the case of a device that performs open-loop control, feedback of the state cannot be obtained from the rolling process information INF01. For such a device, the state at each time point is estimated by interpolation calculation based on the response characteristics such as the assumed change amount or operation amount and the change speed of the actuator, on the assumption that no abnormality occurs in the state. Then, the three-dimensional visualization information INF02 is generated using the estimated value of the state.

The visualization apparatus 11 executes processing PRC02 of transmitting the three-dimensional visualization information INF02. The three-dimensional visualization information INF02 is transmitted to the three-dimensional animation display device 30 and the XR display device 40 by the processing PRC02. The processing PRC01 and the processing PRC02 executed by the visualization apparatus 11 may be executed by the same processor or may be executed by different processors. The visualization apparatus 11 may be configured by a device that executes the processing PRC01 and a device that executes the processing PRC02. The same applies to each processing executed by visualization apparatuses according to second to fourth embodiments described later.

The three-dimensional animation display device 30 performs processing PRC11 to generate a three-dimensional animation ADS01 from the three-dimensional visualization information INF02 and display it. The processing PRC11 uses an equipment three-dimensional model MDL and equipment operation definition information DEF. These are stored in advance in the memory of the three-dimensional animation display device 30. The equipment three-dimensional model MDL is mechanical three-dimensional model information of the rolling equipment and the material to be rolled for three-dimensional display. Information for operating the equipment three-dimensional model MDL is three-dimensional operation information included in the three-dimensional visualization information INF02. Definition information representing how each part of the equipment three-dimensional model MDL operates based on the three-dimensional operation information included in the three-dimensional visualization information INF02 is the equipment operation definition information DEF. The three-dimensional operation information included in the three-dimensional visualization information INF02 can be said to be information for operating the equipment three-dimensional model MDL in accordance with the operation of the actual rolling equipment designated by the rolling process information INF01 and the motion and shape change of the actual material to be rolled. The three-dimensional visualization information INF02 is information that changes according to the rolling process information INF01, whereas the equipment three-dimensional model MDL and the equipment operation definition information DEF are fixed information. However, when there is a modification in the target rolling line, the equipment three-dimensional model MDL and the equipment operation definition information DEF are updated so as to reflect the modification contents.

The three-dimensional animation display device 30 receives the designation of a viewpoint VP from the user interface. In the processing PRC11, the three-dimensional animation ADS01 of the equipment three-dimensional model MDL viewed from the direction of the designated viewpoint is generated. The manager can monitor the operation and state of the rolling equipment and the material to be rolled from various directions by designating an arbitrary viewpoint VP. When the three-dimensional animation display device 30 is integrated with the visualization apparatus 11, the user interface 105 of the visualization apparatus 11 may be used to designate the viewpoint VP.

The XR display device 40 performs processing PRC21 to generate a three-dimensional hologram HDS01 from the three-dimensional visualization information INF02 and display it.

The equipment three-dimensional model MDL and the equipment operation definition information DEF are used for the processing PRC21. These are the same as those used in the three-dimensional animation display device 30, and are stored in advance in the memory of the XR display device 40. For example, a technique of displaying images from different viewpoints to both eyes to visualize the images stereoscopically is used to generate the three-dimensional hologram HDS01. The three-dimensional hologram HDS01 allows the wearer of the device to freely obtain visual three-dimensional information from the viewpoint of the wearer.

### 1-3. Three-Dimensional Display by Visualization System of First Embodiment

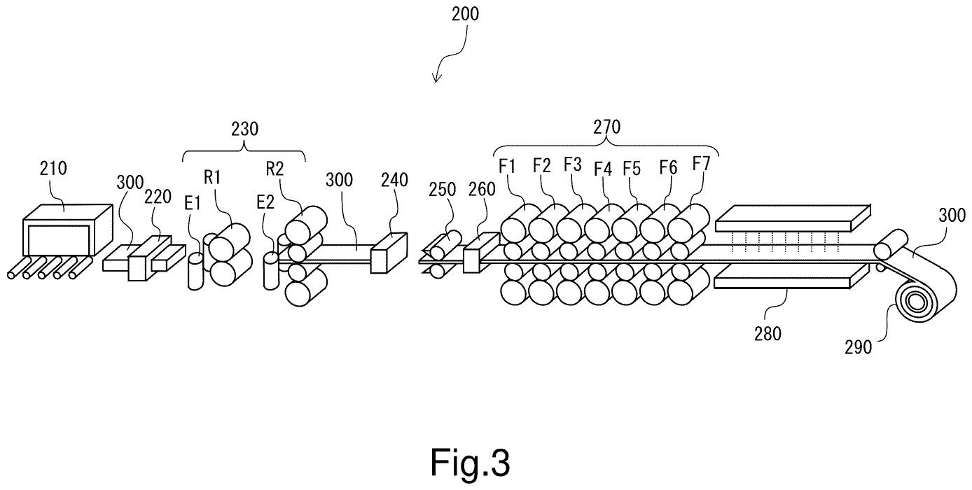

The three-dimensional display by the visualization system 1 having the above-described functions will be described by way of examples with reference to FIGS. 3 to 5. FIGS. 3 to 5 show examples of the three-dimensional animation ADS01 displayed by the three-dimensional animation display device 30. The three-dimensional animation ADS01 is converted into a hologram, which is the three-dimensional hologram HDS01 by the XR display device 40.

FIG. 3 is a view illustrating an example of a three-dimensional display of the rolling line. The rolling line 200 illustrated in FIG. 3 is a hot rolling line, although the visualization system 1 is applicable to both hot rolling lines and cold rolling lines. On the screen of the three-dimensional animation display device 30, rolling equipment such as a heating furnace 210, a sizing press 220, a roughing mill 230, a bar heater 240, a crop shear 250, a descaling device 260, a finishing mill 270, a run-out table 280, and a down coiler 290 constituting the rolling line 200 are three-dimensionally displayed. For the roughing mill 230, for example, a first edger E1, a first horizontal roll stand R1, a second edger E2, and a second horizontal roll stand R2 are three-dimensionally displayed. For the finishing mill 270, for example, seven stands F1 to F7 arranged in series are three-dimensionally displayed. In addition, a material to be rolled 300 which flows through the rolling line 200 is also displayed.

As shown in FIG. 3, by displaying the whole of the rolling line 200 in three dimensions, the operation of each rolling equipment constituting the rolling line 200 and the conveyance state of the material to be rolled 300 flowing through the rolling line 200 can be easily grasped. In particular, the state of the sizing press 220, the roughing mill 230, the crop shear 250, the finishing mill 270, the run-out table 280, the down coiler 290, and the coil box (not illustrated) can be more easily grasped by being visualized by three-dimensional representation than in the case of being represented by numerical values. The positions of leading and trailing ends, dimensions, shape, camber, and vertical warp of the material to be rolled 300 can also be easily grasped by the three-dimensional display.

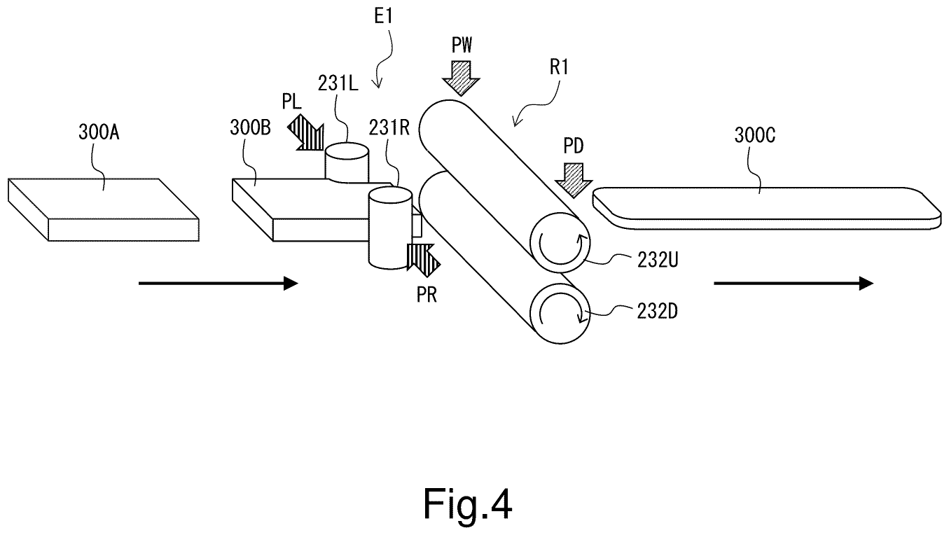

The three-dimensional display by the visualization system 1 can be performed for each rolling equipment constituting the rolling line 200. FIG. 4 is a view illustrating an example of a three-dimensional display of the first edger E1 and the first horizontal roll stand R1 of the roughing mill 230 which is one of the rolling equipment. The left and right edger roll 231L and 231R constituting the first edger El and the upper and lower horizontal roll 232U and 232D constituting the first horizontal roll stand R1 are displayed three-dimensionally. Further, motors for driving the horizontal rolls 232U and 232D, hydraulic cylinders for vertically pressing the horizontal rolls 232U and 232D, and hydraulic cylinders for pressing the edger rolls 231L and 231R in the widthwise direction may be added to the three-dimensional display.

The position, angle, shape, and the like of the material to be rolled 300 are drawn for each stage. In the example of FIG. 4, the three-dimensional shapes of the material to be rolled 300A before being charged into the first edger E1, the material to be rolled 300B during width rolling by the first edger E1, and the material to be rolled 300C after being horizontally rolled by the first horizontal rolling stand R1 are drawn. The end shape of the material to be rolled 300 in the middle of processing, specifically, crop shapes of the leading and trailing ends are essential elements for drawing although there are no measurement values. Therefore, for example, crop shapes assumed from a machining amount are generated by enlarging or reducing a representative dimensional shape stored in advance in accordance with the machining amount. By using such a method, the three-dimensional shape of the material to be rolled 300 during horizontal rolling by the first horizontal rolling stand R1 can also be drawn.

Further, the one-dimensional information of the roughing mill 230 which cannot be represented by the three-dimensional operation is visualized by the three-dimensional representation based on the imaging information. In the example of FIG. 4, arrows that image the rolling load PL and PR in the widthwise direction acting on the first edger El are displayed three-dimensionally. Further, an arrow representing a vertical rolling load PW acting on the work side of the first horizontal roll stand R1 and an arrow representing a vertical rolling load PD acting on the drive side are displayed three-dimensionally. The length, thickness, or color of each arrow indicates the magnitude of the rolling load.

By extracting the roughing mill 230 from the rolling line 200 and displaying the roughing mill 230 in detail in a three-dimensional manner, for example, the camber of the material to be rolled 300 during roughing rolling can be more easily grasped. Further, the state of the roughing mill 230 can be easily grasped by three-dimensionally displaying the images of the rolling load PL, PR in the widthwise direction acting on the first edger El and the rolling load PW, PD in the vertical direction acting on the first horizontal rolling stand R1. By performing the three-dimensional display in real time during the operation of the rolling line 200, accurate manual intervention in control can be performed.

The detailed three-dimensional display for each rolling equipment can be performed for rolling equipment other than the roughing mill 230. For example, when the finish rolling mill 270 is three-dimensionally displayed in detail, meandering of the material to be rolled 300 during finish rolling and the shape of the material to be rolled 300 after completion of finish rolling can be grasped more easily. Although the changes in the thickness of the material 300 to be rolled and the gap between the mill rolls during finish rolling are minute, it is possible to visually grasp these states by enlarging and displaying the finish rolling mill 270 in three dimensions. In addition, when the finishing mill 270 includes a looper, the movement of hunting or the like can be easily grasped by the three-dimensional display. In the case of the down coiler 290, the three-dimensional representation may facilitate distinguishing between four wrapper rolls around a mandrel and may facilitate identifying an abnormal wrapper roll.

The three-dimensional display based on the imaging information can be applied to three-dimensional display of one-dimensional information such as tension, vibration of rolling equipment or motor, current, voltage, and temperature of motor. In the case of tension, the direction and magnitude thereof can be expressed by the length and direction of an arrow. The magnitude of vibration, current, voltage, or temperature can be expressed by color. When the three-dimensional visualization information includes the imaging information, the three-dimensional animation display device 30 and the XR display device 40 generate an image for three-dimensional display from the imaging information by using definition information registered in advance. By combining the three-dimensional display based on the three-dimensional operation information with the three-dimensional display based on the imaging information, the state of the rolling process can be grasped more in detail and easily. For example, when a temperature abnormality of a motor is detected in the run-out table 280, the motor in which the temperature abnormality has occurred can be easily found from among a large number of motors by changing the color of the motor in which the abnormality has been detected.

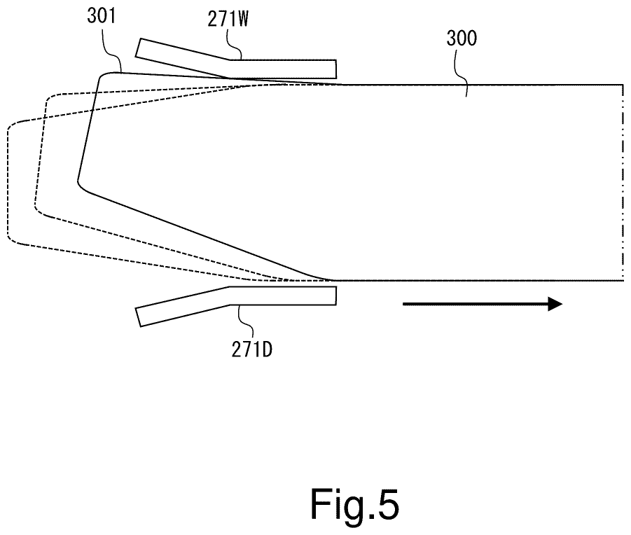

The three-dimensional display by the visualization system 1 can be enlarged so that the motion and the change in shape of the material to be rolled 300 are more clearly displayed. FIG. 5 is a view illustrating an example of a three-dimensional display of the material to be rolled 300. Side guides 271W and 271D are installed on the entry side of each roll stand of the finishing mill 270. In the finishing mill 270, the material to be rolled 300 often enters the rolling stand at a high speed. Therefore, the opening degrees of the side guides 271W and 271D are set to widths obtained by adding margins to the widths of the material to be rolled 300 in advance. FIG. 5 shows the state of the material to be rolled 300 passing between the side guides 271W and 271D, as viewed from directly above.

Although the tail end 301 of the material to be rolled 300 is narrowed, it is difficult to obtain actual measurement values of the dimension and shape of the narrowing. Therefore, for example, when a collision with the side guide 271W or 271D is detected, a change in the shape of the tail end 301 is assumed based on which of the two side guides 271W and 271D the collision has occurred with and the collision position of the material to be rolled 300. The change in shape includes the tail end 301 being cut or folded by the collision. FIG. 5 shows a state in which the tail end 301 of the material to be rolled 300 is bent toward the side guide 271W and collides with the side guide 271W.

### 1-4. Effects of Visualization System of First Embodiment

According to the visualization system 1, three-dimensional visualization information is generated from real-time rolling process information obtained from the rolling line. The manager who manages the rolling line can grasp the state of the rolling process in detail and easily from the three-dimensional visualization information displayed on the three-dimensional display device. This improves equipment maintenance, improves product quality, and improves yield.

### 2. Second Embodiment

### 2-1. Configuration of Visualization System of Second Embodiment

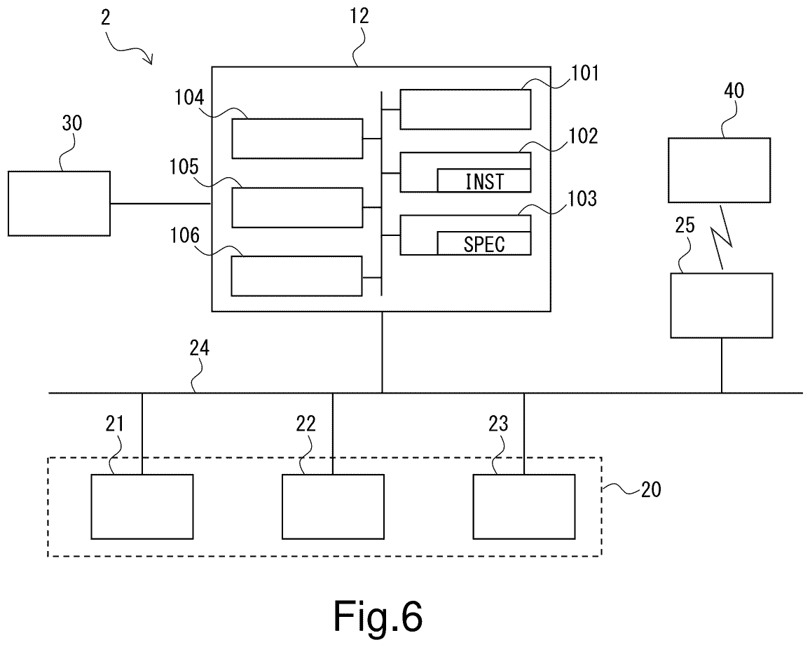

The configuration of a visualization system according to a second embodiment of the present disclosure will be described with reference to FIG. 6. The visualization system 2 according to the present embodiment is different from the visualization system 1 according to the first embodiment in the configuration of the visualization apparatus for visualizing the rolling process information.

A visualization apparatus 12 constituting the visualization system 2 includes an information storage 106 in addition to a processor 101, a program memory 102, a specification information memory 103, a communication module 104, and a user interface 105. The elements other than the information storage 106 are the same as those of the visualization apparatus 11 according to the first embodiment, and thus the description thereof will be omitted. However, in order to realize a function unique to the present embodiment described later, the instructions INST according to the present embodiment stored in the program memory 102 is different in content from the instructions INST according to the first embodiment.

The information storage 106 is communicatively coupled to the processor 101. The information storage 106 stores three-dimensional visualization information output to the three-dimensional animation display device 30 and the XR display device 40. The information storage 106 includes a database for managing three-dimensional visualization information. The date and time when the three-dimensional visualization information is recorded in the information storage 106 are managed in the database, and thus the three-dimensional visualization information at an arbitrary time in the past can be read from the information storage 106. The information storage 106 may be built in the visualization apparatus 12 or may be externally attached to the visualization apparatus 12.

### 2-2. Functions of Visualization System of Second Embodiment

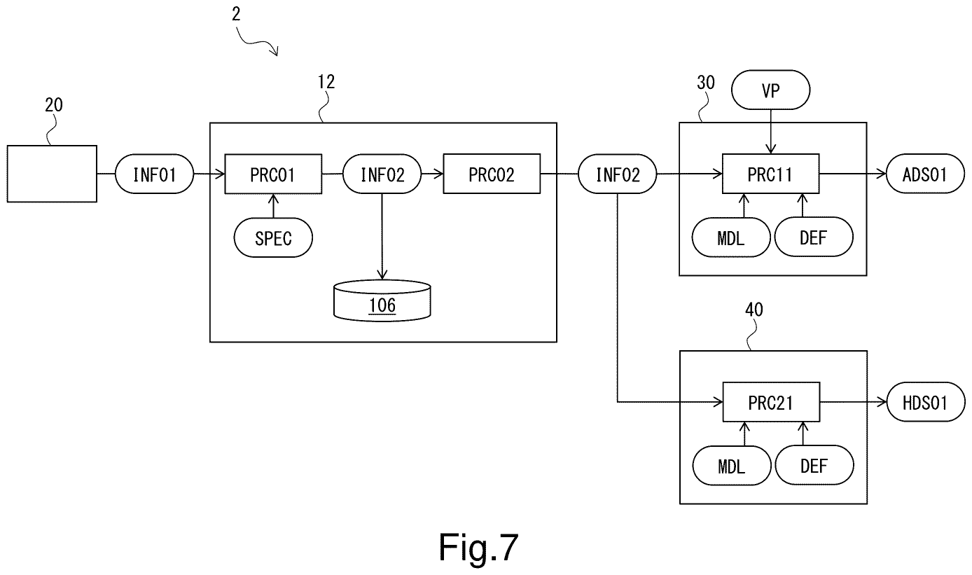

The functions of the visualization system 2 configured as described above will be described with reference to FIGS. 7 to 12. However, the description of the same processing as the processing executed by the visualization system 1 according to the first embodiment will be omitted or simplified. Further, the description of information having the same contents as the information used in the visualization system 1 according to the first embodiment will be omitted or simplified. Note that, among the functions of the visualization system 2 described below, the functions of the visualization apparatus 12 are functions realized by the instructions INST according to the present embodiment being read from the program memory 102 and executed by the processor 101.

FIG. 7 shows a real-time display function of three-dimensional visualization information, which is a first function of the visualization system 2. The visualization apparatus 12 generates the three-dimensional visualization information INF02 using the rolling process information INFO1 acquired in real time from the control system 20 and the specification information SPEC. The visualization apparatus 12 transmits the three-dimensional visualization information INF02 to the three-dimensional animation display device 30 and the XR display device 40, and accumulates all the generated three-dimensional visualization information INF02 in the information storage 106.

The processing executed by the three-dimensional animation display device 30 and the XR display device 40 in response to the input of the three-dimensional visualization information INF02 is the same as that in the visualization system 1.

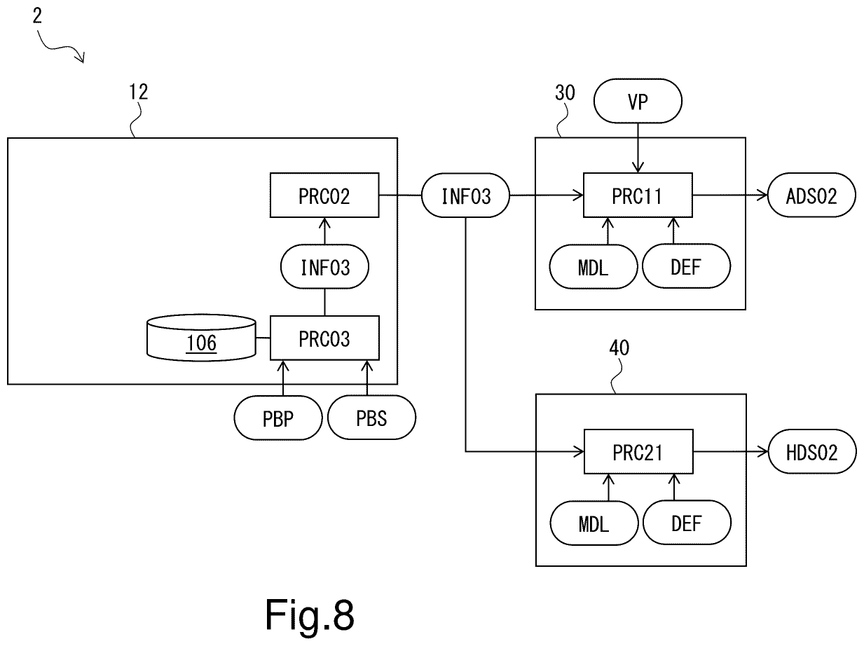

FIG. 8 shows a function of reproducing and displaying past three-dimensional visualized information, which is a second function of the visualization system 2. The visualization apparatus 12 receives an input of a designated period PBP and an input of a designated speed PBS, and executes processing PRC03 in accordance with the designated period PBP and the designated speed PBS. The user interface 105 is used to input the designated period PBP and the designated speed PBS. The processing PRC03 is processing of reading the three-dimensional visualization information INF03 corresponding to the designated period PBP from the information storage 106 and reproducing the three-dimensional visualization information INF03 at the designated speed PBS. The designated period PBP is determined by a reproduction start time and a reproduction end time. However, the reproduction may be started by designating only the reproduction start time, and the reproduction may be ended at an arbitrary time after the reproduction start. The visualization apparatus 12 executes the processing PRC02 and transmits the three-dimensional visualization information INF03 to the three-dimensional animation display device 30 and the XR display device 40.

The three-dimensional animation display device 30 generates and displays a three-dimensional animation ADS02 from the three-dimensional visualization information INF03 by the processing PRC11. The three-dimensional animation ADS02 is displayed at the designated speed PBS for the designated period PBP. The XR display device 40 generates and displays a three-dimensional hologram HDS02 from the three-dimensional visualization information INF03 by the processing PRC21. The three-dimensional hologram HDS02 is displayed at the designated speed PBS for the designated period PBP.

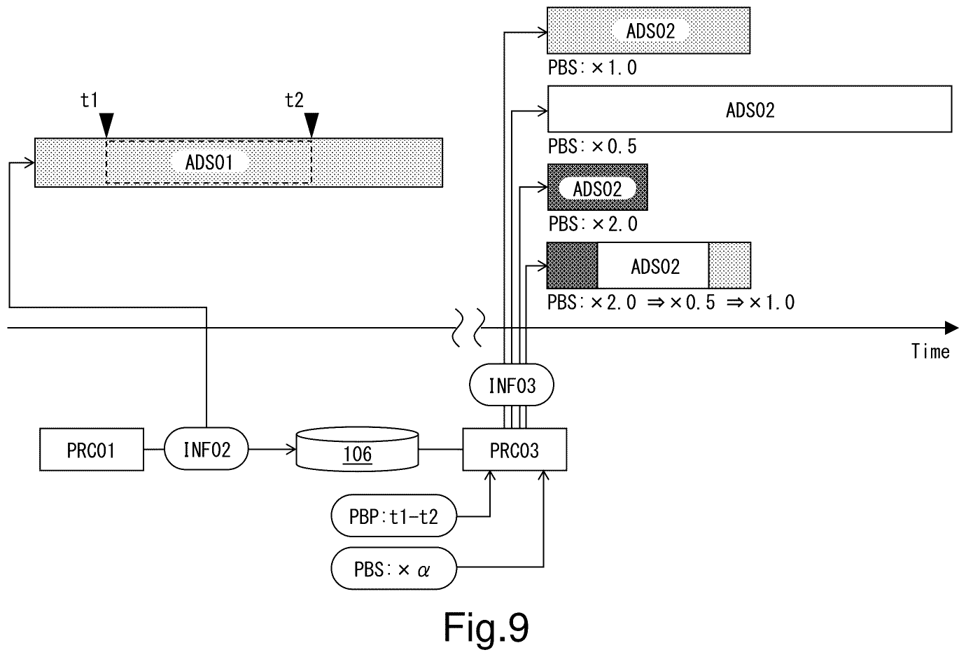

FIG. 9 is a diagram illustrating an example of a display mode of a three-dimensional animation by the real-time display function and the reproduction display function of the visualization system 2. In parallel with the display of the three-dimensional animation ADS01, the three-dimensional visualization information INF02 which is the basis of the three-dimensional animation ADS01 is accumulated in the information storage 106. The manager can grasp the state of the rolling process by the three-dimensional animation ADS01 displayed in real time.

After the end of the three-dimensional animation ADS01, the manager may want to review a certain scene again. In such a case, the manager operates the user interface 105 of the visualization apparatus 12 to input a period to be checked as the designated period PBP. In the example shown in FIG. 9, the period from time t1 to time t2 is input as the designated period PBP. The manager can also input the designated speed PBS by operating the user interface 105 of the visualization apparatus 12. The designated speed PBS is set to normal speed as standard.

The three-dimensional visualization information INF03 corresponding to the designated period PBP is read from the information storage 106, and the read three-dimensional visualization information INF03 is reproduced at the designated speed PBS. The manager can reconfirm the state of the rolling process by the display of the three-dimensional animation ADS02 generated from the three-dimensional visualization information INF03.

FIG. 9 shows, in order from the top, the reproduction period of the three-dimensional animation ADS02 when the designated speed PBS is the normal speed (×1.0), the reproduction period of the three-dimensional animation ADS02 when the designated speed PBS is the 0.5-fold speed (×0.5), and the reproduction period of the three-dimensional animation ADS02 when the designated speed PBS is the 2-fold speed (×2.0). In this way, the designated speed PBS can be made faster or slower than the normal speed. The lowermost row shows the reproduction period of the three-dimensional animation ADS02 when the designated speed PBS is varied in the order of 2× speed, 0.5× speed, and normal speed. By changing the designated speed PBS in this way, it is possible to suppress the overall reproduction time while carefully observing the scene of interest.

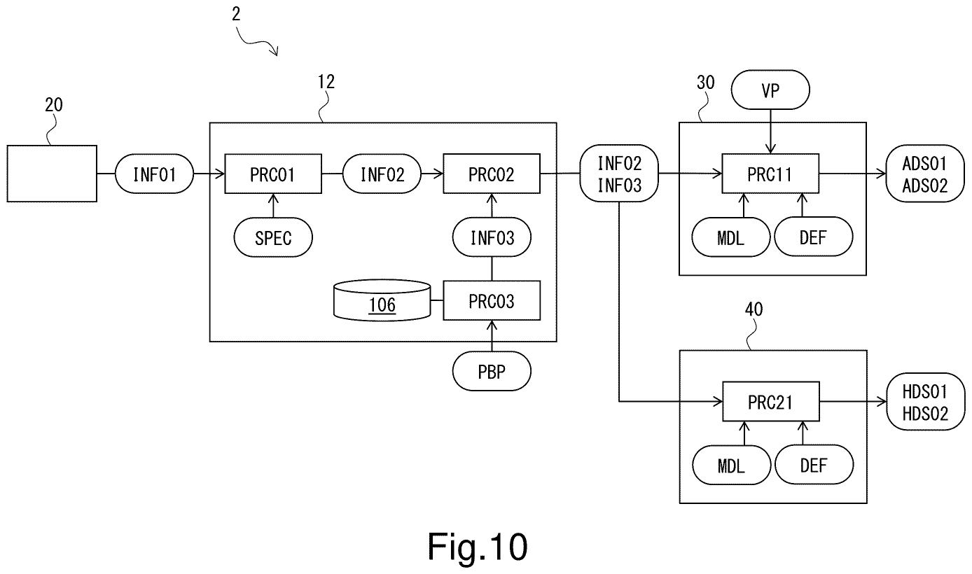

FIG. 10 shows a function of simultaneously displaying real-time three-dimensional visualization information and past three-dimensional visualization information, which is a third function of the visualization system 2. The visualization apparatus 12 executes the processing PRC01 on the rolling process information INF01 acquired in real time from the control system 20, and generates the three-dimensional visualization information INF02 using the rolling process information INF01 and the specification information SPEC. In parallel with the processing PRC01, the visualization apparatus 12 receives the input of the designated period PBP, executes the processing PRC03, and reads the three-dimensional visualization information INF03 corresponding to the designated period PBP from the information storage 106. When the simultaneous display function is used, the designated speed PBS of the three-dimensional visualization information INF03 is fixed to the normal speed. The visualization apparatus 12 executes the processing PRC02, and transmits the three-dimensional visualization information INF02 and the three-dimensional visualization information INF03 to the three-dimensional animation display device 30 and the XR display device 40.

The three-dimensional animation display device 30 performs the processing PRC11 to generate the three-dimensional animation ADS01 from the three-dimensional visualization information INF02 and generate the three-dimensional animation ADS02 from the three-dimensional visualization information INF03. The XR display device 40 performs the processing PRC21 to generate a three-dimensional hologram HDS01 from the three-dimensional visualization information INF02 and generate a three-dimensional hologram HDS02 from the three-dimensional visualization information INF03.

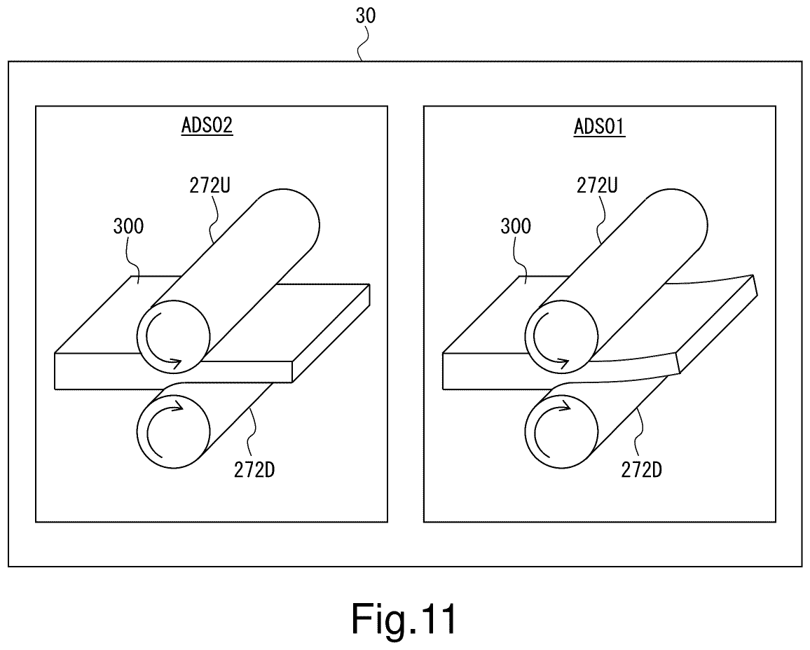

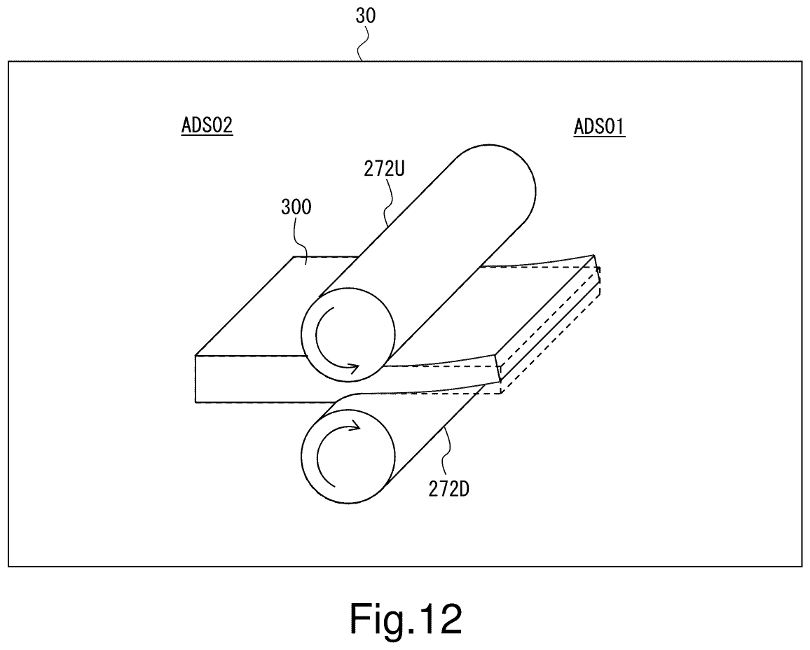

FIGS. 11 and 12 are diagrams illustrating examples of display modes of three-dimensional animations by the simultaneous display function of the visualization system 2. In the first display mode shown in FIG. 11, the three-dimensional animation display device 30 displays the three-dimensional animation ADS01 and the three-dimensional animation ADS02 in parallel.

The three-dimensional animation ADS01 represents the operation of the upper and lower mill rolls 272U and 272D and the state of the material to be rolled 300 at the current time. The three-dimensional animation ADS02 represents the operation of the upper and lower mill rolls 272U and 272D and the state of the material to be rolled 300 at the designated time in the past. The manager can easily grasp a change in the operation of the mill rolls 272U and 272D and a change in the state of the material to be rolled 300 by comparing the three-dimensional animation ADS01 with the three-dimensional animation ADS02. The display screen for displaying the three-dimensional animation ADS01 and the display screen for displaying the three-dimensional animation ADS02 may be separate screens.

In the second display mode shown in FIG. 12, the three-dimensional animation display device 30 displays the three-dimensional animation ADS02 in a superimposed manner on the three-dimensional animation ADS01. In FIG. 12, the three-dimensional animation ADS01 is indicated by a broken line, and the three-dimensional animation ADS02 is indicated by a solid line. By superimposing the three-dimensional animation ADS02 on the three-dimensional animation ADS01, the manager can more easily grasp a change in the operation of the mill roll 272U and 272D and a change in the state of the material to be rolled 300.

### 2-3. Effects of Visualization System of Second Embodiment

According to the visualization system 2, the three-dimensional visualization information reproduced from an arbitrary time in the past is displayed on the three-dimensional display device. The manager who manages the rolling line can easily grasp the state of the past rolling process in detail from the three-dimensional visualization information displayed on the three-dimensional display device. This improves the accuracy of failure analysis, leading to improvement in product quality. Further, since all the generated three-dimensional visualization information is accumulated in the information storage 107, a plurality of three-dimensional visualization information at different times can be displayed in parallel or in a superimposed manner.

### 3. Third Embodiment

### 3-1. Configuration of Visualization System of Third Embodiment

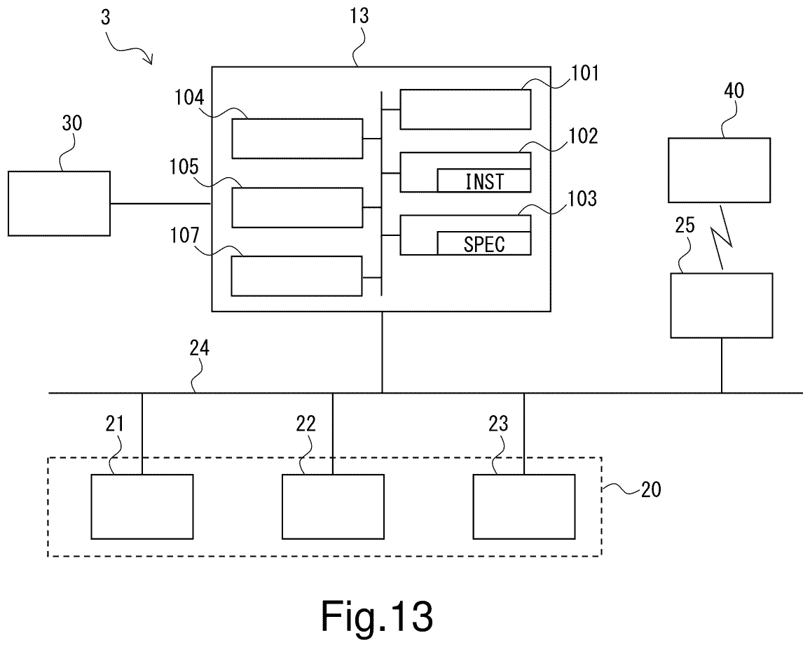

The configuration of at visualization system according to a third embodiment of the present disclosure will be described with reference to FIG. 13. The visualization system 3 according to the present embodiment is different from the visualization system 1 according to the first embodiment in the configuration of the visualization apparatus for visualizing the rolling process information.

The visualization apparatus 12 constituting the visualization system 3 includes an information storage 107 in addition to a processor 101, a program memory 102, a specification information memory 103, a communication module 104, and a user interface 105. The elements other than the information storage 107 are the same as those of the visualization apparatus 11 according to the first embodiment, and thus the description thereof will be omitted. However, in order to realize a function unique to the present embodiment described later, the instructions INST according to the present embodiment stored in the program memory 102 is different in content from the instructions INST according to the first embodiment.

The information storage 107 is communicatively coupled to the processor 101. The information storage 107 stores the rolling process information acquired from the control system 20. The information storage 107 includes a database for managing the rolling process information. The date and time when the rolling process information is recorded in the information storage 107 are managed by the database, and thus the rolling process information from an arbitrary time in the past can be read from the information storage 107. The information storage 107 may be built in the visualization apparatus 12 or may be externally attached to the visualization apparatus 12.

### 3-2. Functions of Visualization System of Third Embodiment

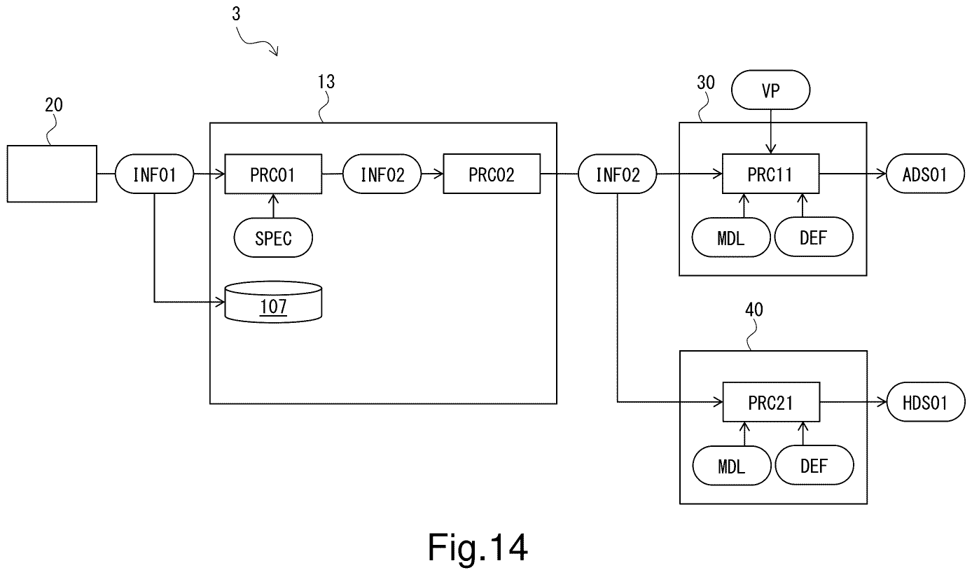

The functions of the visualization system 3 configured as described above will be described with reference to FIGS. 14 to 16. However, the description of the same processing as the processing executed by the visualization system 1 or the visualization system 2 will be omitted or simplified. Further, the description of information having the same contents as the information used in the visualization system 1 or the visualization system 2 will be omitted or simplified. Note that, among the functions of the visualization system 3 described below, the functions of the visualization apparatus 13 are functions realized by the instructions INST according to the present embodiment being read from the program memory 102 and executed by the processor 101.

FIG. 14 shows a real-time display function of three-dimensional visualization information, which is a first function of the visualization system 3. The visualization apparatus 13 generates the three-dimensional visualization information INF02 using the rolling process information INF01 acquired in real time from the control system 20 and the specification information SPEC, and accumulates all the acquired rolling process information INF01 in the information storage 107. The visualization apparatus 13 transmits the three-dimensional visualization information INF02 to the three-dimensional animation display device 30 and the XR display device 40.

The processing executed by the three-dimensional animation display device 30 and the XR display device 40 in response to the input of the three-dimensional visualization information INF02 is the same as that in the visualization system 1.

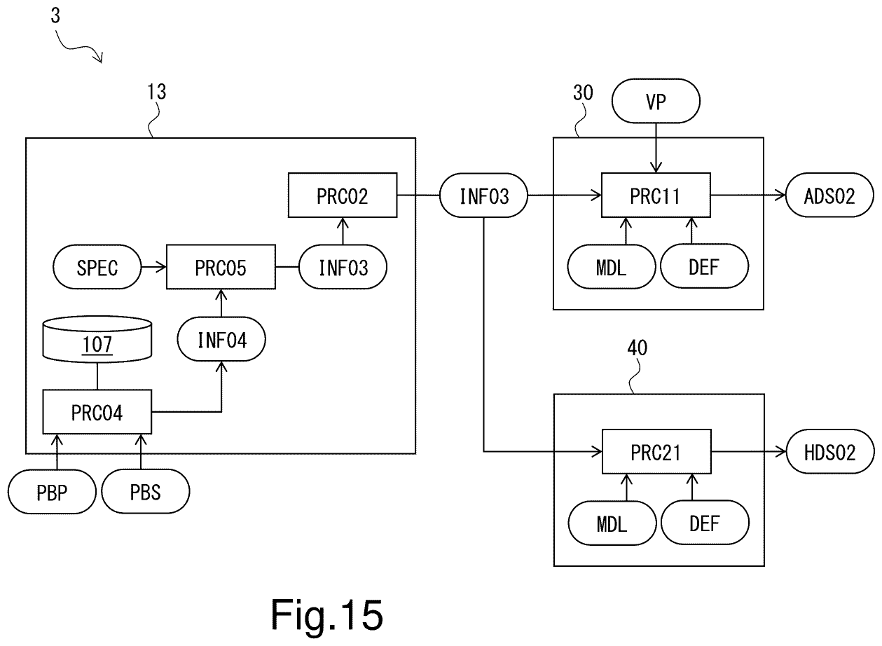

FIG. 15 shows a function of reproducing and displaying past three-dimensional visualized information, which is a second function of the visualization system 3. The visualization apparatus 13 receives an input of the designated period PBP and an input of the designated speed PBS, and executes the processing PRC04 in accordance with the designated period PBP and the designated speed PBS. The user interface 105 is used to input the designated period PBP and the designated speed PBS. The processing PRC04 is processing of reading the rolling process information INF04 corresponding to the designated period PBP from the information storage 107 and reproducing the read information at the designated speed PBS. The designated period PBP is determined by the reproduction start time and the reproduction end time. However, the reproduction may be started by designating only the reproduction start time, and the reproduction may be ended at an arbitrary time after the reproduction start.

The visualization apparatus 13 executes the processing PRC05 using the generated rolling process information INF04 and the specification information SPEC. The processing PRC05 is processing of generating the three-dimensional visualization information INF03 in the designated period PBP. The three-dimensional visualization information INF03 is generated by editing and integrating the rolling process information INF04 based on the specification information SPEC. The visualization apparatus 12 executes the processing PRC02 and transmits the three-dimensional visualization information INF03 to the three-dimensional animation display device 30 and the XR display device 40.

The processing executed by the three-dimensional animation display device 30 and the XR display device 40 in response to the input of the three-dimensional visualization information INF03 is the same as that in the visualization system 2.

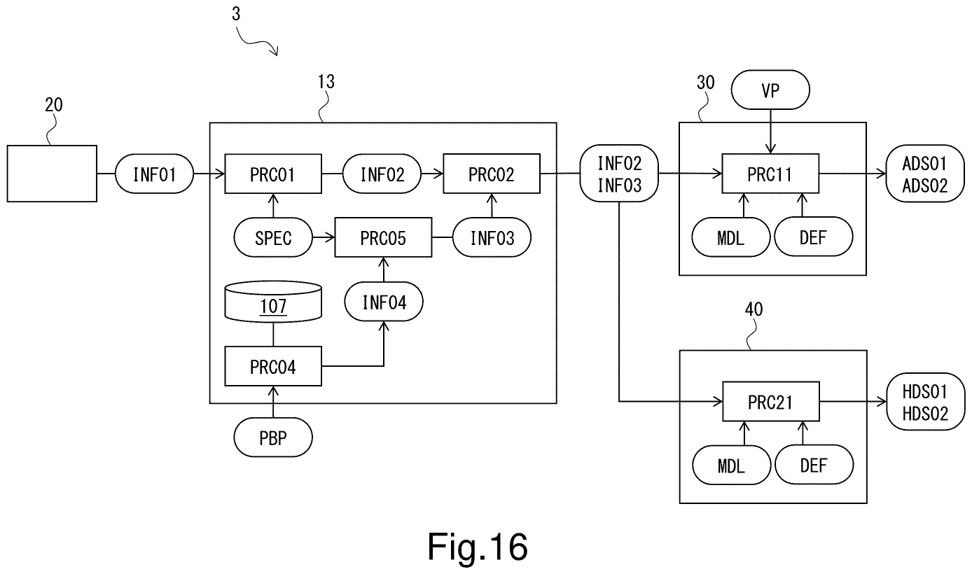

FIG. 16 shows a function of simultaneously displaying the real-time three-dimensional visualization information and the past three-dimensional visualization information, which is a third function of the visualization system 3. The visualization apparatus 13 executes the processing PRC01 on the rolling process information INF01 acquired in real time from the control system 20, and generates the three-dimensional visualization information INF02 using the rolling process information INF01 and the specification information SPEC.

In parallel with the processing PRC01, the visualization apparatus 13 executes the processing PRC04 in response to the input of the designated period PBP, and reads the rolling process information INF04 corresponding to the designated period PBP from the information storage 107. Further, the visualization apparatus 13 executes the processing PRC05 on the rolling process information INF04 read from the information storage 107, and generates the three-dimensional visualization information INF03 using the rolling process information INF04 and the specification information SPEC. The visualization apparatus 12 executes the processing PRC02, and transmits the three-dimensional visualization information INF02 and the three-dimensional visualization information INF03 to the three-dimensional animation display device 30 and the XR display device 40.

The processing executed by the three-dimensional animation display device 30 and the XR display device 40 in response to the input of the three-dimensional visualization information INF02 and the three-dimensional visualization information INF03 is the same as that in the visualization system 2.

### 3-3. Effects of Visualization System of Third Embodiment

According to the visualization system 3, the three-dimensional visualization information is generated using the rolling process information reproduced from an arbitrary time in the past, and the three-dimensional visualization information is displayed on the three-dimensional display device. The manager who manages the rolling line can grasp the state of the past rolling process in detail and easily from the three-dimensional visualization information displayed on the three-dimensional display device. Further, since the history of all the information included in the rolling process information is stored in the information storage 107, the manager can analyze the displayed three-dimensional visualization information together with the history of the stored information. The resulting improvement in the accuracy of the fault analysis improves equipment maintenance, improves product quality, and improves yield.

### 4. Fourth Embodiment

### 4-1. Configuration of Visualization System of Fourth Embodiment

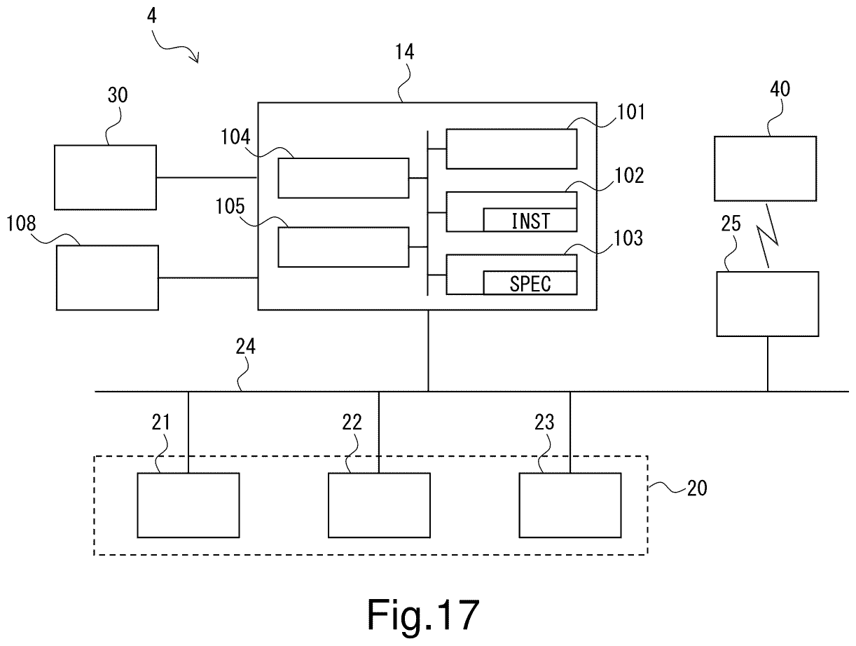

The configuration of a visualization system according to a fourth embodiment of the present disclosure will be described with reference to FIG. 17. The visualization system 4 according to the present embodiment is different from the visualization system 1 according to the first embodiment in the configuration of the visualization apparatus for visualizing the rolling process information.

The visualization apparatus 14 constituting the visualization system 4 includes a simulation information generator 108 in addition to the processor 101, the program memory 102, the specification information memory 103, the communication module 104, and the user interface 105. Since the elements other than the simulation information generator 108 are the same as those of the visualization apparatus 11 according to the first embodiment, the description thereof will be omitted.

The simulation information generator 108 is communicatively coupled to the processor 101. The simulation information generator 108 is a device for generating simulation information simulating the rolling process information. The simulation information may be information simulating normal rolling process information or information simulating abnormal rolling process information. The rolling process information that is the basis of the simulation information may be information actually acquired from the control system 20 or may be artificially created information. The simulation information generator 108 may be externally attached to the visualization apparatus 14 or may be incorporated therein.

### 4-2. Functions of Visualization System of Fourth Embodiment

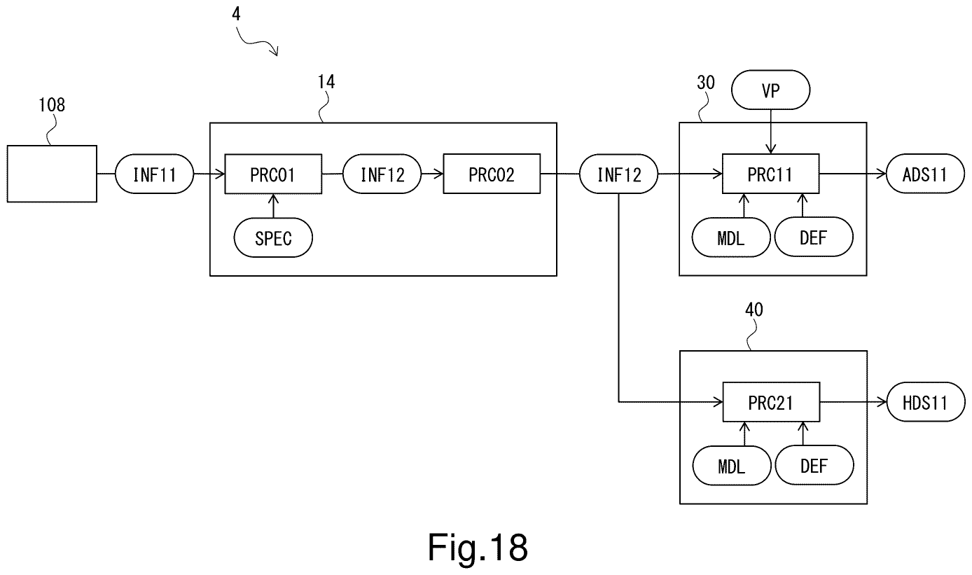

The functions of the visualization system 3 configured as described above will be described with reference to FIG. 18. However, the description of the same processing as the processing executed by the visualization system 1 will be omitted or simplified. Further, the description of information having the same contents as the information used in the visualization system 1 will be omitted or simplified. Note that, among the functions of the visualization system 3 described below, the functions of the visualization apparatus 14 are functions realized by the instructions INST according to the present embodiment being read from the program memory 102 and executed by the processor 101.

The visualization apparatus 14 executes the processing PRC01 on the simulation information INF11 acquired from the simulation information generator 108, and generates simulated three-dimensional visualization information INF12 using the simulation information INF11 and the specification information SPEC. Then, the visualization apparatus 14 executes the processing PRC02 and transmits the simulated three-dimensional visualization information INF12 to the three-dimensional animation display device 30 and the XR display device 40.

The three-dimensional animation display device 30 generates a three-dimensional animation ADC11 from the simulated three-dimensional visualization information INF12 by the processing PRC11. The XR display device 40 generates a three-dimensional hologram HDS11 from the simulated three-dimensional visualization information INF12 by the processing PRC21.

### 4-3. Effects of Visualization System of Fourth Embodiment

According to the visualization system 4, the simulated three-dimensional visualization information is generated using the simulation information obtained by simulating the rolling process information, and the simulated three-dimensional visualization information is displayed on the three-dimensional display device. The manager who manages the rolling line can grasp the state of the simulated rolling in detail and easily from the simulated three-dimensional visualization information displayed on the three-dimensional display device. In particular, when information simulating the normal rolling process information is used as the simulation information, the manager can find a bug in the equipment three-dimensional model or a bug in the equipment operation definition information based on an abnormality in the display contents of the three-dimensional display device. In addition, when information simulating the abnormal rolling process information is used as the simulation information, the manager can grasp in advance a problem that may occur in the rolling line based on an abnormality in the display contents of the three-dimensional display device.

### DESCRIPTION OF SYMBOLS

1, 2, 3, 4 Visualization system
11, 12, 13, 14 Visualization apparatus
20 Control system
24 Control network
25 Wireless communication device
30 Three-dimensional animation display device
40 XR display device
101 Processor
102 Program memory
103 Specification information memory
104 Communication module
105 User interface
106 Information storage
107 Information storage
108 Simulation information generator

1.-3. (Canceled)

4. An apparatus for visualizing rolling process information of a rolling line, comprising:
a specification information memory in which specification information of each of rolling equipment installed in the rolling line and a material to be rolled processed in the rolling line is registered;
a program memory storing a plurality of executable instructions;
one or more processors communicatively coupled to the specification information memory and the program memory; and
an information storage,
wherein the plurality of instructions is configured to cause the one or more processors to:
acquire the rolling process information in real time from a control system that controls the rolling line,
generate three-dimensional visualization information for visualizing at least one of the rolling equipment and the material to be rolled in a three-dimensional representation using the rolling process information and the specification information,
display the three-dimensional visualization information on a display device,
store the three-dimensional visualization information in the information storage,
receive a designated period input to a user interface,
acquire the three-dimensional visualization information for the designated period from the information storage, and
display the three-dimensional visualization information for the designated period on the display device.

5. The apparatus for visualizing rolling process information according to claim 4, wherein the plurality of instructions is configured to cause the one or more processors to:
receive a designated speed input to the user interface, and
display the three-dimensional visualization information for the designated period on the display device at the designated speed.

6. The apparatus for visualizing rolling process information according to claim 4, wherein the plurality of instructions is configured to cause the one or more processors to display the three-dimensional visualization information and the three-dimensional visualization information for the designated period in parallel on the display device.

7. The apparatus for visualizing rolling process information according to claim 4, wherein the plurality of instructions is configured to cause the one or more processors to display the three-dimensional visualization information and the three-dimensional visualization information for the designated period in a superimposed manner on the display device.

8. An apparatus for visualizing rolling process information of a rolling line, comprising:
a specification information memory in which specification information of each of rolling equipment installed in the rolling line and a material to be rolled processed in the rolling line is registered;
a program memory storing a plurality of executable instructions;
one or more processors communicatively coupled to the specification information memory and the program memory; and
an information storage, wherein the plurality of instructions is configured to cause the one or more processors to:
acquire the rolling process information in real time from a control system that controls the rolling line,
generate three-dimensional visualization information for visualizing at least one of the rolling equipment and the material to be rolled in a three-dimensional representation using the rolling process information and the specification information,
display the three-dimensional visualization information on a display device,
store the rolling process information in the information storage,
receive a designated period input to a user interface,
acquire the rolling process information for the designated period from the information storage,
generate three-dimensional visualization information of at least one of the rolling equipment and the material to be rolled for the designated period using the rolling process information and the specification information for the designated period, and
display the three-dimensional visualization information for the designated period on the display device.

9. An apparatus for visualizing rolling process information of a rolling line, comprising:
a specification information memory in which specification information of each of rolling equipment installed in the rolling line and a material to be rolled processed in the rolling line is registered;
a program memory storing a plurality of executable instructions;
one or more processors communicatively coupled to the specification information memory and the program memory; and
a simulation information generator configured to generate simulation information simulating the rolling process information, wherein the plurality of instructions is configured to cause the one or more processors to:
acquire the rolling process information in real time from a control system that controls the rolling line,
generate three-dimensional visualization information for visualizing at least one of the rolling equipment and the material to be rolled in a three-dimensional representation using the rolling process information and the specification information,
display the three-dimensional visualization information on a display device,
generate simulated three-dimensional visualization information of at least one of the
rolling equipment and the material to be rolled using the simulation information and the specification information, and
display the simulated three-dimensional visualization information on the display device.

10. The apparatus for visualizing rolling process information according to claim 9, wherein the simulation information is information simulating normal rolling process information.

11. The apparatus for visualizing rolling process information according to claim 9, wherein the simulation information is information simulating abnormal rolling process information.
